(19) United States
(12) Patent Application Publication
(10) Pub. No.: US 2012/0067396 A1
(43) Pub. Date: Mar. 22, 2012

(54) Hydrophobic Solar Concentrator and Method of Using and Forming the Hydrophobic Solar Concentrator

(76) Inventors: Visvamohan Yegnashankaran, Cupertino, CA (US); Akshey Sehgal, Scarborough, ME (US); Jamal Ramdani, Scarborough, ME (US)

(21) Appl. No.: 12/884,345

(22) Filed: Sep. 17, 2010

(51) Int. Cl. H01L 31/052; H01B 13/00; B05D 5/12

(52) U.S. Cl. 136/246; 427/74; 216/13

(57) ABSTRACT

A solar concentrator is implemented with a plate structure that has a surface and one or more hydrophobic regions on the surface of the plate structure. The plate structure is transparent to visible light. A fluid is sprayed onto the surface of the plate structure where the fluid forms droplets on the hydrophobic regions. The droplets capture substantially all angles of incident solar radiation and deliver concentrated solar radiation to a corresponding number of solar cells.

### BACKGROUND OF THE INVENTION

1. Field of the Invention

The present invention relates to a solar concentrator and, more particularly, to a hydrophobic solar concentrator and a method of using and forming the hydrophobic solar concentrator.

2. Description of the Related Art

A solar concentrator is a device that focuses a large area of light onto a smaller area. The focused light output by a solar concentrator increases the heat delivered to the smaller area. As a result, solar concentrators are used with turbines to heat the fluid that drives the turbines.

The focused light also increases the density of photons. As a result, solar concentrators are used with solar panels to direct more photons to the photovoltaic cells within the panels and thereby increase the efficiency of the cells. The heat generated by a solar concentrator, however, reduces the efficiency and can melt and otherwise damage the solar panels. As a result, a solar panel must be cooled to dissipate the heat that is generated by a solar concentrator.

Solar concentrators are commonly realized with arrangements of mirrors, trapped air, and lenses. Further, in order to maintain the same focal point, solar concentrators are mounted on tracking systems that follow the sun as the sun moves across the sky. These tracking systems, however, require a large upfront capital investment, higher maintenance, and more land to prevent adjacent solar panels from shadowing each other. Thus, due to the cooling requirements, large upfront capital investment, higher maintenance costs, and increased land requirements, solar concentrators have not made a successful transition to high-volume manufacturing.

Another approach to solar concentration, which is described in Currie et al., “High-Efficiency Organic Solar Concentrators for Photovoltaics” Science, Vol. 321, No. 5886, July 2008, pp. 226-228, is to use organic solar concentrators. An organic solar concentrator utilizes thin coatings of organic dyes that absorb sunlight and reemit favored wavelengths into a pane of glass. The light is aimed and concentrated towards the edge of the glass pane where inorganic solar cells are located to collect the light.

One of the advantages of the organic solar concentrator discussed by Currie et al is that the organic solar concentrator requires no cooling. Another advantage is that the organic solar concentrator allows the solar panels to produce the maximum possible amount of energy all day every day without complex sun-tracking mechanisms.

However, one disadvantage of the organic solar concentrator discussed by Currie et al is that the organic dyes used in the concentrator have a demonstrated lifespan of approximately 10 years. Most solar panels, however, require a 20 or 25 year lifespan to be economically competitive with traditional power sources. Thus, the dye-coated glass of an organic solar concentrator must be replaced multiple times during the product lifecycle, thereby significantly increasing the cost of this approach.

As a result, there is a need for a solar concentrator which is inexpensive, does not require cooling and sun-tracking mechanisms, and requires no part replacement during the product lifecycle.

### BRIEF DESCRIPTION OF THE DRAWINGS

FIG. 1 is a cross-sectional view illustrating an example of a hydrophobic solar concentrator 100 in accordance with the present invention.

FIG. 2 is a cross-sectional view illustrating an example of a hydrophobic solar concentrator 200 in accordance with the present invention.

FIGS. 3A-3B are views illustrating an example of a hydrophobic solar concentrator 300 in accordance with the present invention. FIG. 3A is a plan view, while FIG. 3B is a cross-sectional view taken along line 3B-3B of FIG. 3A.

FIGS. 4A-4B are views illustrating an example of a hydrophobic solar panel 400 in accordance with the present invention. FIG. 4A is a plan view of solar panel 400, while FIG. 4B is a cross-sectional view of solar panel 400 taken along line 4B-4B of FIG. 4A.

FIGS. 5A-5B are views illustrating an example of a hydrophobic solar panel 500 in accordance with the present invention. FIG. 5A is a plan view of solar panel 500, while FIG. 5B is a cross-sectional view of solar panel 500 taken along line 5B-5B of FIG. 5A.

FIGS. 6A-6C are views illustrating an example of a hydrophobic solar panel 600 in accordance with the present invention. FIG. 6A is a plan view of solar panel 600, while FIG. 6B is a cross-sectional view of solar panel 600 taken along line 6B-6B of FIG. 6A, and FIG. 6C is a cross-sectional view of solar panel 600 taken along line 6C-6C of FIG. 6A.

FIG. 7 is a cross-sectional view of a portion of hydrophobic solar concentrator 300 illustrating the operation of concentrators 100, 200, and 300 in accordance with the present invention.

FIGS. 8A-8C are cross-sectional views illustrating a method of forming hydrophobic solar concentrator 300 in accordance with the present invention.

### DETAILED DESCRIPTION OF THE INVENTION

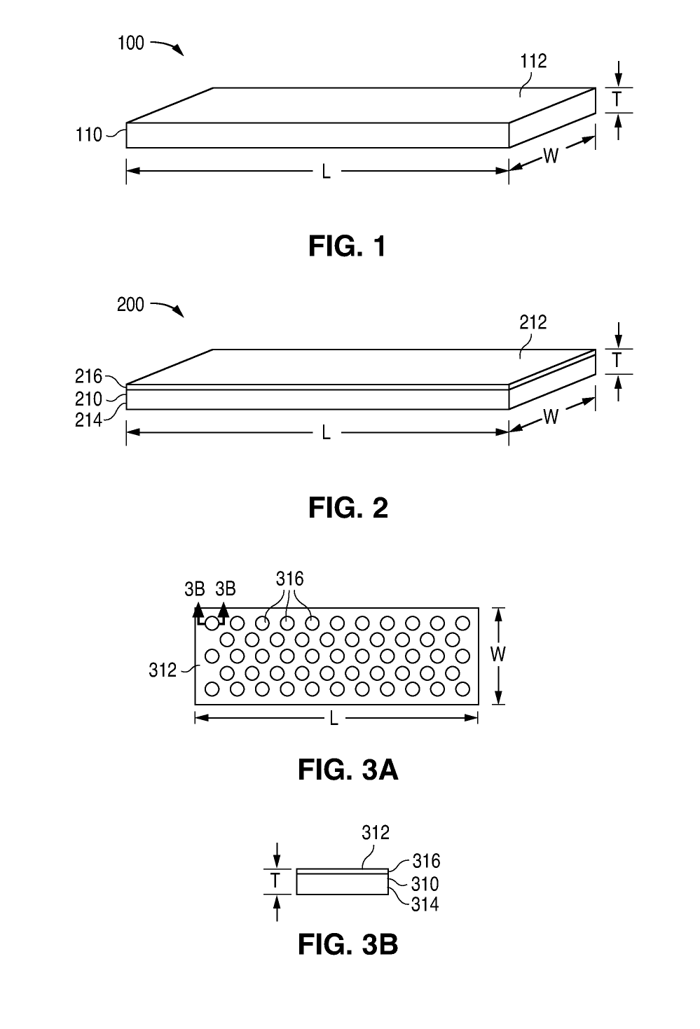

FIG. 1 shows a cross-sectional view that illustrates an example of a hydrophobic solar concentrator 100 in accordance with the present invention. As shown in FIG. 1, hydrophobic solar concentrator 100 includes a plate structure 110 that is transparent to visible light. Plate structure 110 has a length L, a width W, and a thickness T that is substantially less than the width W.

Further, in accordance with the present invention, plate structure 110 has an exterior surface 112 that is hydrophobic. Although not required, exterior surface 112 of plate structure 110 is preferably superhydrophobic. A superhydrophobic surface is a surface where a droplet contacting the surface has a contact angle that is greater than 90°.

Plate structure 110 can be implemented with, for example, a plastic such as a high temperature plastic like Zytel HTN, which is a polyamide manufactured by Dupont. High temperature plastics are both transparent to visible light and hydrophobic. As a result, a plastic has an exterior surface that is hydrophobic.

FIG. 2 shows a cross-sectional view that illustrates an example of a hydrophobic solar concentrator 200 in accordance with the present invention. As shown in FIG. 2, hydrophobic solar concentrator 200 includes a plate structure 210 that is transparent to visible light. Plate structure 210 has a length L, a width W, and a thickness T that is substantially less than the width W.

Further, like plate structure 110, plate structure 210 has an exterior surface 212 that is hydrophobic. Although not required, exterior surface 212 of plate structure 210 is preferably superhydrophobic. In addition, plate structure 210 also includes a first region 214 and a second region 216 that touches first region 214. First region 214 lies below second region 216, and second region 216 has a greater hydrophobicity than first region 214.

Plate structure 210 can be implemented in a number of different ways. For example, first region 214 can be implemented with glass, which is transparent to visible light, and second region 216 can be implemented with an organic-based, transparent, hydrophobic material that is attached to the glass. A polymer, such as polypropylene, which is an organic-based material that is hydrophobic and transparent to visible light, can be attached to glass. As a result, glass with an overlying organic-based, transparent, hydrophobic material has an exterior surface that is hydrophobic.

In addition, when first region 214 is glass and second region 216 is an organic-based, transparent, hydrophobic material, second region 216 has a greater hydrophobicity than first region 214 because glass is hydrophilic. In other words, glass has no hydrophobicity. Thus, a second region of an organic-based, transparent, hydrophobic material has a greater hydrophobicity than a first region of glass which has no hydrophobicity.

Alternately, first region 214 can be implemented with glass, and second region 216 can be implemented with an abraded region of the glass, which has a roughened surface like fine sandpaper. Although glass is hydrophilic and has no hydrophobicity, an abraded glass surface is hydrophobic. As a result, glass with an abraded exterior surface has an exterior surface that is hydrophobic.

In addition, when first region 214 is glass and second region 216 is an abraded region of the glass, second region 216 has a greater hydrophobicity than first region 214 because glass is hydrophilic and abraded glass is hydrophobic. Thus, a second region of abraded glass has a greater hydrophobicity than a first region of glass which has no hydrophobicity.

Alternately, first region 214 can be implemented with a plastic such as a high temperature plastic like Zytel HTN, and second region 216 can be implemented with an organic-based, transparent, hydrophobic material, such as a polymer like polypropylene, that is attached to the plastic. As a result, a plastic with an overlying organic-based, transparent, hydrophobic material has an exterior surface that is hydrophobic.

In addition, when first region 214 is a plastic and second region 216 is an organic-based, transparent, hydrophobic material, second region 216 can have a greater hydrophobicity than first region 214 by selecting the organic-based, transparent, hydrophobic material to have a greater hydrophobicity than the plastic. For example, a polymer, such as polypropylene, has a greater hydrophobicity than the high temperature plastic Zytel HTN. Thus, a second region of an organic-based, transparent, hydrophobic material can have a greater hydrophobicity than a first region of plastic.

Alternately, first region 214 can be implemented with a plastic such as a high temperature plastic like Zytel HTN, and second region 216 can be implemented as an abraded region of the plastic, which has a roughened surface like fine sandpaper. An abraded plastic surface is hydrophobic. As a result, a plastic with an abraded exterior surface has an exterior surface that is hydrophobic.

In addition, when first region 214 is a plastic and second region 216 is an abraded region of the plastic, second region 216 has a greater hydrophobicity than first region 214 because abraded plastic has a greater hydrophobicity than non-abraded plastic. Thus, a second region of abraded plastic has a greater hydrophobicity than a first region of non-abraded plastic.

FIGS. 3A-3B show views that illustrate an example of a hydrophobic solar concentrator 300 in accordance with the present invention. FIG. 3A shows a plan view, while FIG. 3B shows a cross-sectional view taken along line 3B-3B of FIG. 3A. As shown in FIGS. 3A-3B, hydrophobic solar concentrator 300 includes a plate structure 310 that is transparent to visible light. In addition, plate structure 310 has an exterior surface 312, a length L, a width W, and a thickness T that is substantially less than the width W.

Further, plate structure 310 also includes a first region 314 and a number of completely spaced apart second regions 316 that touch first region 314. Each second region 316, in turn, has a greater hydrophobicity than first region 314. Although not required, each second region 316 is preferably superhydrophobic.

Plate structure 310 can be implemented in a number of different ways. For example, first region 314 and each second region 316 can be implemented with the same combinations that can be used to implement first region 214 and second region 216. Thus, first region 314 can be implemented with glass, and each second region 316 can be implemented with an organic-based, transparent, hydrophobic material that is attached to the glass.

Alternately, first region 314 can be implemented with glass, and each second region 316 can be implemented with an abraded region of the glass, which has a roughened surface like fine sandpaper. Thus, when first region 310 is implemented with glass, plate structure 310 has a hydrophobic exterior surface and a hydrophilic exterior surface.

Alternately, first region 314 can be implemented with a plastic such as a high temperature plastic like Zytel HTN, and each second region 316 can be implemented with an organic-based, transparent, hydrophobic material, such as a polymer like polypropylene, that is attached to the plastic. Alternately, first region 314 can be implemented with a plastic such as a high temperature plastic like Zytel HTN, and each second region 316 can be implemented as an abraded region of the plastic, which has a roughened surface like fine sandpaper. Thus, when first region 310 is implemented with a plastic, plate structure 310 has a hydrophobic exterior surface.

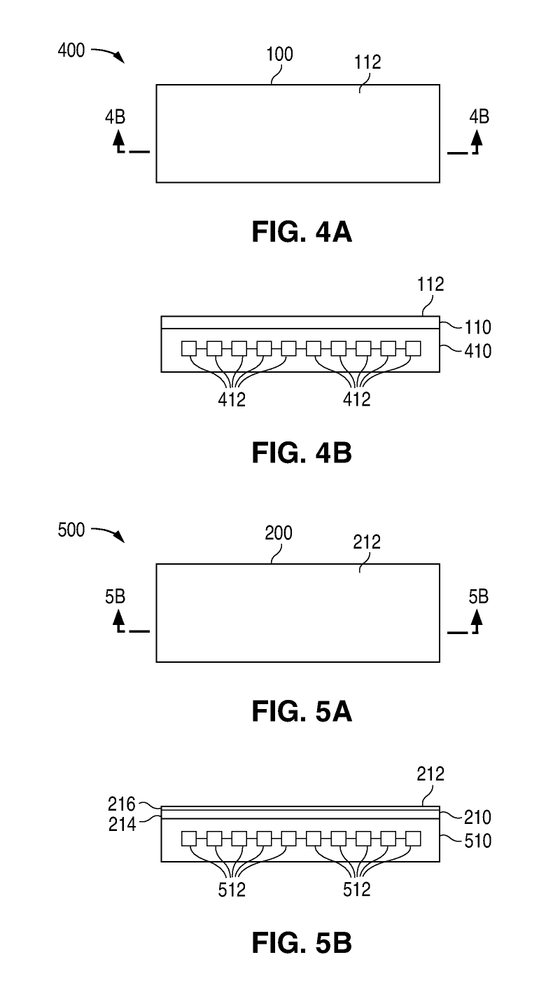

FIGS. 4A-4B show views that illustrate an example of a hydrophobic solar panel 400 in accordance with the present invention. FIG. 4A shows a plan view of solar panel 400, while FIG. 4B shows a cross-sectional view of solar panel 400 taken along line 4B-4B of FIG. 4A. As shown in FIGS. 4A and 4B, hydrophobic solar panel 400 includes hydrophobic solar concentrator 100, and a solar structure 410 that touches hydrophobic solar concentrator 100.

Solar structure 410 is a conventionally formed assembly that includes a number of spaced-apart photovoltaic (or solar) cells 412. The photovoltaic cells 412 are electrically connected together to produce electricity with practical voltage and current levels. Each photovoltaic cell 412, which collects photons that pass through hydrophobic solar concentrator 100 and converts the photons into electricity via the photoelectric effect, generates a small portion of the total electricity produced by the solar panel.

FIGS. 5A-5B show views that illustrate an example of a hydrophobic solar panel 500 in accordance with the present invention. FIG. 5A shows a plan view of solar panel 500, while FIG. 5B shows a cross-sectional view of solar panel 500 taken along line 5B-5B of FIG. 5A. As shown in FIGS. 5A and 5B, hydrophobic solar panel 500 includes hydrophobic solar concentrator 200, and a solar structure 510 that touches hydrophobic solar concentrator 200.

Solar structure 510 is a conventionally formed assembly that includes a number of spaced-apart photovoltaic (or solar) cells 512. The photovoltaic cells 512 are electrically connected together to produce electricity with practical voltage and current levels. Each photovoltaic cell 512, which collects photons that pass through hydrophobic solar concentrator 200 and converts the photons into electricity via the photoelectric effect, generates a small portion of the total electricity produced by the solar panel.

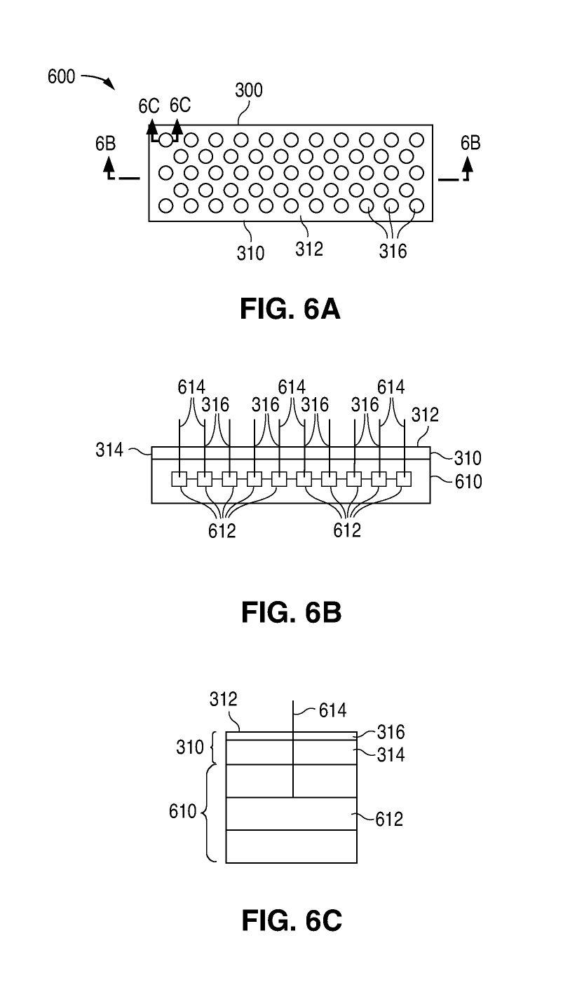

FIGS. 6A-6C show views that illustrate an example of a hydrophobic solar panel 600 in accordance with the present invention. FIG. 6A shows a plan view of solar panel 600, while FIG. 6B shows a cross-sectional view of solar panel 600 taken along line 6B-6B of FIG. 6A, and FIG. 6C shows a cross-sectional view of solar panel 600 taken along line 6C-6C of FIG. 6A. As shown in FIGS. 6A-6C, hydrophobic solar panel 600 includes hydrophobic solar concentrator 300, and a solar structure 610 that touches hydrophobic solar concentrator 300.

Solar structure 610 is a conventionally formed assembly that includes a number of spaced-apart photovoltaic (or solar) cells 612 that correspond with the number of second regions 316. The photovoltaic cells 612 are electrically connected together to produce electricity with practical voltage and current levels. Each photovoltaic cell 612, which collects photons that pass through a second region 316 of hydrophobic solar concentrator 300 and converts the photons into electricity via the photoelectric effect, generates a small portion of the total electricity produced by the solar panel.

As further shown in FIGS. 6A-6C, the second regions 316 can be aligned with the photovoltaic cells 612 so that each of a number of lines 614 passes through a second region 316 and a corresponding photovoltaic cell 612. Each of the number of lines 614, in turn, lies perpendicular to exterior surface 312 of plate 310.

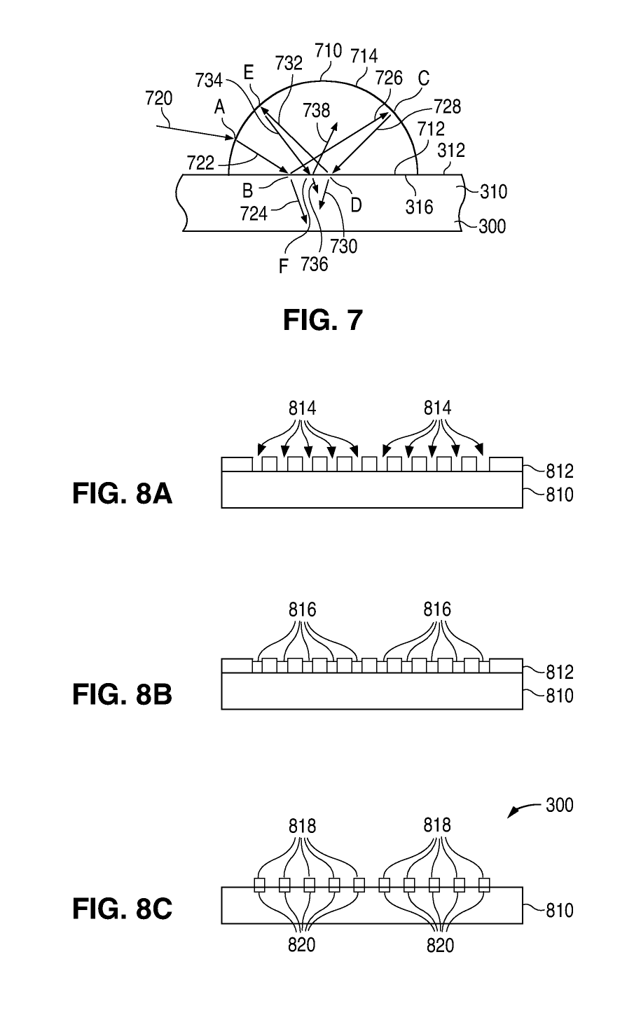

FIG. 7 shows a cross-sectional view of a portion of hydrophobic solar concentrator 300 that illustrates the operation of concentrators 100, 200, and 300 in accordance with the present invention. In operation, a liquid is periodically applied to exterior surface 312 of plate structure 310 to form droplets 710 on the hydrophobic second regions 316.

Each droplet 710 has a surface 712 that contacts a hydrophobic second region 316, and a surface 714 that is exposed to the environment. The droplets 710 on the hydrophobic second regions 316 capture substantially all angles of incident solar radiation and deliver concentrated solar radiation to the photovoltaic cells that underlie plate structure 310.

For example, as shown in FIG. 7, a light ray 720 strikes surface 714 of a droplet 710 at point A. A portion of ray 720 reflects away from surface 714, while a portion penetrates surface 714 and propagates on as ray 722. Ray 722 propagates through droplet 710 with an altered direction due to refraction and strikes surface 712 at point B. A portion of ray 722 penetrates surface 712 and enters a photovoltaic cell underlying plate structure 310 as ray 724, thereby generating electron-hole pairs, while a portion of ray 722 reflects away from surface 712 as ray 726.

Ray 726 strikes surface 714 at point C. A portion of ray 726 penetrates surface 714 and escapes, while a portion of ray 726 reflects off of surface 714 as ray 728. Ray 728 strikes surface 712 at point D. A portion of ray 728 penetrates surface 712 and enters the photovoltaic cell underlying plate structure 310 as ray 730, thereby generating electron-hole pairs, while a portion of ray 728 reflects away from surface 712 as ray 732.

Ray 732 strikes surface 714 at point E. A portion of ray 732 penetrates surface 714 and escapes, while a portion of ray 732 reflects off of surface 714 as ray 734. Ray 734 strikes surface 712 at point F. A portion of ray 734 penetrates surface 712 and enters the photovoltaic cell underlying plate structure 310 as ray 736, thereby generating electron-hole pairs, while a portion of ray 734 reflects away from surface 712 as ray 738.

Thus, due to the multiple internal reflections provided by droplets on a hydrophobic surface, such as exterior surface 112 of concentrator 100, second region 216 of concentrator 200, or the second regions 316 of concentrator 300, a significant portion of the original light ray is captured by the solar concentrators 100, 200, and 300.

Without hydrophobic solar concentrator 100, 200, or 300, a light ray would generate substantially fewer electron-hole pairs. Therefore, hydrophobic solar concentrators 100, 200, and 300 capture substantially all angles of incident solar radiation and direct the captured solar radiation to the photovoltaic cells.

The liquid periodically applied can be a high surface tension liquid, which has large intermolecular forces and generally large polarity (ability to dissolve materials into itself). Although it is preferable to use a liquid with high surface tension, it is not required and low surface tension liquids can also be used. (Liquids with low surface tension such as ethanol and diethyl ether can be used to dissolve surface grime and still be made to bead up on a rough surface.)

The liquid used to form the droplets 310 can be implemented with a number of different liquids as indicated in the following TABLE.

TABLE

| Liquid | Temperature ° C. | Surface Tension |
|---|---|---|
| Acetic acid | 20 | 27.6 |
| Acetic acid (40.1% + Water | 30 | 40.68 |
| Acetic acid (10.0% + Water | 30 | 54.56 |
| Acetone | 20 | 23.7 |
| Diethyl ether | 20 | 17.0 |
| Ethanol | 20 | 22.27 |
| Ethanol (40.0%) + Water | 25 | 29.63 |
| Ethanol (11.1%) + Water | 25 | 46.03 |
| Glycerol | 20 | 63 |
| n-Hexane | 20 | 18.4 |
| Isopropanol | 20 | 21.7 |
| Methanol | 20 | 22.6 |
| n-Octane | 20 | 21.8 |
| Water | 0 | 75.64 |
| Water | 25 | 71.97 |
| Water | 50 | 67.91 |
| Water | 100 | 58.85 |

In addition, although it is preferable to use a liquid that readily dissolves accumulated dust and grime on the exterior surface of a concentrator, it is not required and liquids that less readily dissolve accumulated dust and grime can also be used. Water is the preferred liquid because of the low cost and ready availability of water.

The liquid can be can be applied automatically such as with a mister or sprayer, or manually such as with a hose. The liquid is misted or sprayed on a plate structure multiple times each day at a predefined time so that droplets are substantially always present on the hydrophobic surfaces during the time that radiation from the sun can be captured. For example, the liquid can be applied while the sun is up on a fixed time schedule, e.g., every 10 minutes, or based on a calculated evaporation rate (e.g., based on temperature, humidity, and wind speed).

The liquid can be applied at a single flow rate, or at different flow rates as long as the liquid beads up and forms droplets on the hydrophobic surfaces. For example, a heavy flow rate can be used to remove the accumulated dust and grime, followed by a light flow rate to form droplets on the hydrophobic surfaces.

One of the advantages of the present invention is that the present invention eliminates the need to cool the photovoltaic cells. This is because the solar radiation entering a photovoltaic cell is not concentrated at a focal point. For example, rays 724, 730, and 736 in FIG. 7 are not concentrated at a focal point.

Another advantage of the present invention is that the present invention does not require a tracking system to track the movement of the sun across the sky. In addition to eliminating the cost associated with a tracking system, the elimination of a tracking system also allows a greater density of solar panels for a given area since no panel will shadow an adjacent panel.

Hydrophobic solar concentrator 100 can be formed by obtaining an appropriately sized sheet of a plastic, such as a high temperature plastic like Dupont's Zytel HTN. Hydrophobic solar concentrator 200 can be formed by obtaining an appropriately sized sheet of plate material, such as glass or a plastic such as a high temperature plastic like Dupont's Zytel HTN, and then forming a hydrophobic region of the top surface of the sheet of plate material.

For example, an organic-based material, such as polypropylene, can be melted and deposited on the sheet of plate material. Alternately, rather than depositing an organic-based material, a chemical etchant can be applied to roughen up the surface of the plate material for fluids to bead up. Following the etch, the etchant is rinsed away. Etchants that rough up the surface of glass or high temperature plastic are well known in the art. The surface can also be roughened mechanically using, for example, a diamond saw.

FIGS. 8A-8C show cross-sectional views that illustrate a method of forming hydrophobic solar concentrator 300 in accordance with the present invention. As shown in FIG. 8A, the method utilizes an appropriately sized sheet of plate material 810, and begins by applying a pattern 812 to sheet 810. The sheet of plate material 810, which is transparent to visible light, can be implemented with glass or a plastic such as a high temperature plastic like Dupont's Zytel HTN. Pattern 812, in turn, has a number of openings 814 that expose the top surface of sheet 810.

Following this, as shown in FIG. 8B, a hydrophobic material 816 is deposited on sheet 810 to fill up the openings 814 in pattern 812. For example, an organic-based material, such as polypropylene, can be melted and deposited. As shown in FIG. 8C, after hydrophobic material 816 has been deposited, pattern 812 is lifted off, thereby leaving a pattern of hydrophobic regions 818 on the surface of sheet 810 that forms hydrophobic solar concentrator 300.

Alternately, rather than depositing an organic-based material, a chemical etchant can be applied to roughen up the surface of sheet 810 for fluids to bead up. Etchants that rough up the surface of glass or plastic are well known in the art. In this case, pattern 812 must be resistant to the etchant.

Following the etch, the etchant is rinsed away and pattern 812 is removed in a conventional manner, thereby leaving a pattern of hydrophobic abraded regions 820 on the surface of sheet 810 that forms hydrophobic solar concentrator 300. The surface of sheet 810 can also be roughened mechanically with or without a pattern or jig using, for example, a diamond saw to form hydrophobic solar concentrator 300.

The hydrophobic solar concentrators 100, 200, and 300 can be attached to a solar structure, like solar structures 410, 510, and 610, to form a hydrophobic solar panel. Alternately, the steps illustrated in FIGS. 4A-4C can be applied to the surface of the top plate of an existing solar panel, such as a solar panel which is already in service. Thus, the hydrophobic solar concentrator of the present invention can be retrofitted to units already in service, or used as a finishing treatment applied to new solar panels as a part of a high volume manufacturing process.

Therefore, a hydrophobic solar concentrator, a method of using the hydrophobic solar concentrator, and a method of making the hydrophobic solar concentrator have been described that provide an inexpensive, reliable way of concentrating incident solar radiation and, thereby, improving the conversion efficiency of the solar panel. In addition, the hydrophobic solar concentrator of the present invention requires no expensive parts or electronics.

It should be understood that the above descriptions are examples of the present invention, and that various alternatives of the invention described herein may be employed in practicing the invention. Thus, it is intended that the following claims define the scope of the invention and that structures and methods within the scope of these claims and their equivalents be covered thereby.

What is claimed is:

1. A hydrophobic solar concentrator comprising a plate structure, the plate structure being transparent to visible light and having a first region and a second region, the first region lying below and touching the second region, the second region having a greater hydrophobicity than the first region.

2. The hydrophobic solar concentrator of claim 1 wherein the plate structure includes a plurality of laterally adjacent second regions that touch the first region, have a greater hydrophobicity than the first region, and lie completely spaced apart from each other.

3. The hydrophobic solar concentrator of claim 2 wherein each second region is attached to the first region.

4. The hydrophobic solar concentrator of claim 2 wherein each second region is an abraded region of the first region.

5. A solar panel comprising:
a plate structure being transparent to visible light and having a first region and a second region, the first region lying below and touching the second region, the second region having a greater hydrophobicity than the first region; and
a solar structure that touches the plate structure, the solar structure including a plurality of solar cells.

6. The solar panel of claim 5 wherein the plate structure includes a plurality of laterally adjacent second regions that touch the first region, have a greater hydrophobicity than the first region, and lie completely spaced apart from each other.

7. The solar panel of claim 6 wherein the plurality of laterally adjacent second regions are aligned with the plurality of solar cells by a plurality of lines that each lie perpendicular to the surface of the plate structure so that each line passes through a second region and a corresponding solar cell.

8. The solar panel of claim 7 wherein each second region is attached to the first region.

9. The solar panel of claim 7 wherein each second region is an abraded region of the first region.

10. A method of operating a solar panel comprising spraying a liquid on a plate structure multiple times during a day at a predefined time, the plate structure being transparent to visible light and having an exterior surface, the exterior surface being hydrophobic.

11. The method of claim 10 wherein the solar panel includes a solar structure that touches the plate structure, the solar structure including a plurality of solar cells.

12. The method of claim 11 wherein the plate structure has a first region and a second region, the first region lying below and touching the second region, the second region having a greater hydrophobicity than the first region.

13. The method of claim 12 wherein the plate structure includes a plurality of laterally adjacent second regions that touch the first region, have a greater hydrophobicity than the first region, and lie completely spaced apart from each other.

14. A method of forming a solar concentrator comprising forming a hydrophobic region on a surface of a plate structure, the plate structure being transparent to visible light, the hydrophobic region being transparent to visible light.

15. The method of claim 14 wherein forming the hydrophobic region includes forming a polymer that touches the surface of the plate structure.

16. The method of claim 14 wherein forming the hydrophobic region includes abrading the surface of the plate structure.

17. The method of claim 14 wherein forming the hydrophobic region includes:
placing a pattern on the surface of the plate structure, the pattern having a plurality of openings that extend through the pattern;
forming a polymer that touches the pattern and the surface of the plate structure, and fills up the plurality of openings; and
removing the pattern.

18. The method of claim 14 wherein forming the hydrophobic region includes:
placing a pattern on the surface of the plate structure, the pattern having a plurality of openings that extend through the pattern;
etching the surface of the plate structure exposed by the pattern to roughen the surface of the plate structure; and
removing the pattern.

19. The method of claim 14 wherein the plate structure is glass.

20. The method of claim 14 wherein the plate structure is plastic.
